(19) United States
(12) Patent Application Publication
(10) Pub. No.: US 2016/0233260 A1
(43) Pub. Date: Aug. 11, 2016

(54) CHIP PACKAGE AND METHOD FOR FORMING THE SAME

(71) Applicant: XINTEC INC., Taoyuan City (TW)

(72) Inventors: Ho-Yin YIU, KLN (HK); Ying-Nan WEN, Hsinchu City (TW); Chien-Hung LIU, New Taipei City (TW)

(21) Appl. No.: 15/013,135

(22) Filed: Feb. 2, 2016

Related U.S. Application Data
(60) Provisional application No. 62/112,550, filed on Feb. 5, 2015.

(51) Int. Cl. H01L 27/146; H01L 31/18; H01L 31/0232; H01L 31/0216

(52) U.S. Cl. CPC H01L 27/14627; H01L 31/0216; H01L 31/1876; H01L 31/1868; H01L 31/02327; H01L 27/14685; H01L 27/1462; H01L 27/14698; H01L 27/14621; H01L 27/14636

(57) ABSTRACT

An embodiment of the invention provides a chip package which includes a first substrate including a device region and having a first surface and a second surface opposite thereto. A dielectric layer is disposed on the second surface of the first substrate and includes a conducting pad structure connected to the device region, and the first substrate completely covers the conducting pad structure. A second substrate is disposed on the second surface of the first substrate and the dielectric layer is located between the first substrate and the second substrate. The second substrate has a first opening exposing a surface of the conducting pad structure, and a redistribution layer is conformally disposed on a sidewall of the first opening and the surface of the exposed conducting pad structure. A method for forming the chip package is also provided.

### CROSS REFERENCE TO RELATED APPLICATIONS

This application claims the benefit of U.S. Provisional Application No. 62/112,550 filed Feb. 5, 2015, the entirety of which is incorporated by reference herein, the entirety of which is incorporated by reference herein.

### BACKGROUND OF THE INVENTION

1. Field of the Invention

The invention relates to chip package technology, and in particular to a chip package and methods for forming the same.

2. Description of the Related Art

The chip packaging process is an important step in the fabrication of electronic products. Chip packages not only protect the chips therein from outer environmental contaminants, but they also provide electrical connection paths between the electronic elements inside and those outside of the chip packages.

In conventional chip package fabrication, a surface of the conducting pad structure in a dielectric layer is typically exposed in the step of circuit probing (CP), so as to test the electronic properties of the wafer with probing tools.

Using such chip package fabrication, however, the manufacturing costs may increase and the structural strength of the chip package may be reduced, which decreases its reliability.

Accordingly, there exists a need in the art for development of a chip package and methods for forming the same capable of mitigating or eliminating the aforementioned problems.

### BRIEF SUMMARY OF THE INVENTION

An embodiment of the invention provides a chip package which includes a first substrate including a device region and having a first surface and a second surface opposite thereto. A dielectric layer is disposed on the second surface of the first substrate and includes a conducting pad structure electrically connected to the device region, and the first substrate completely covers the conducting pad structure. A second substrate is disposed on the second surface of the first substrate and the dielectric layer is located between the first substrate and the second substrate. The second substrate has a first opening exposing a surface of the conducting pad structure. A redistribution layer is conformally disposed on a sidewall of the first opening and the surface of the exposed conducting pad structure.

An embodiment of the invention provides a method for forming a chip package. The method includes providing a first substrate that includes a device region and has a first surface and a second surface opposite thereto. The second surface of the first substrate has a dielectric layer thereon and the dielectric layer includes a conducting pad structure electrically connected to the device region, wherein the first substrate does not have an opening exposing the conducting pad structure. A second substrate is formed on the second surface of the first substrate, wherein the dielectric layer is located between the first substrate and the second substrate. A first opening passing through the second substrate and extending into the dielectric layer to expose a surface of the conducting pad structure is formed. A redistribution layer is conformally formed on a sidewall of the first opening and the surface of the exposed conducting pad structure. The second substrate and the first substrate are successively diced.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1G are cross-sectional views of an exemplary embodiment of a method for forming a chip package according to the invention;

FIG. 2 is a cross-sectional view of another exemplary embodiment of a chip package according to the invention;

FIG. 3 is a cross-sectional view of yet another exemplary embodiment of a chip package according to the invention;

FIGS. 4A to 4E are cross-sectional views of another exemplary embodiment of a method for forming a chip package according to the invention;

FIG. 5A is a bottom view of the region enclosed by a dashed line in the chip package shown in FIG. 1C;

FIG. 5B is a bottom view of the region enclosed by a dashed line in the chip package shown in FIG. 4A.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Furthermore, when a first material layer is referred to as being on or overlying a second material layer, the first material layer may be in direct contact with the second material layer, or spaced apart from the second material layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multilayer integrated circuit devices by stacking (stack) a plurality of wafers having integrated circuits.

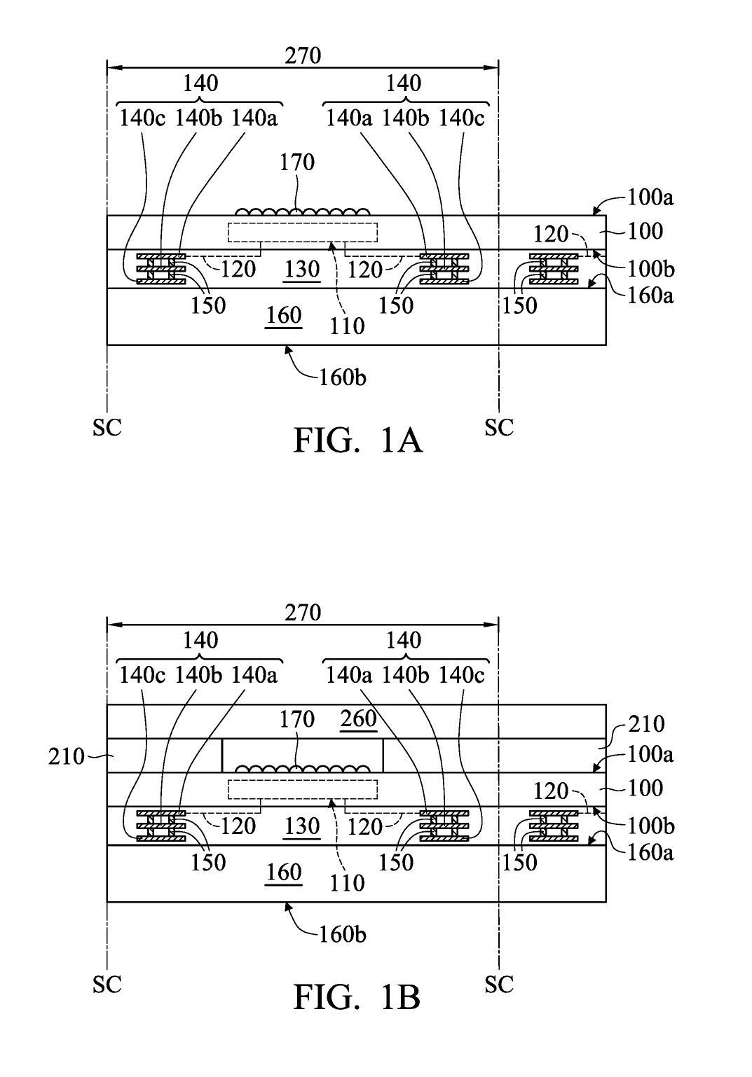

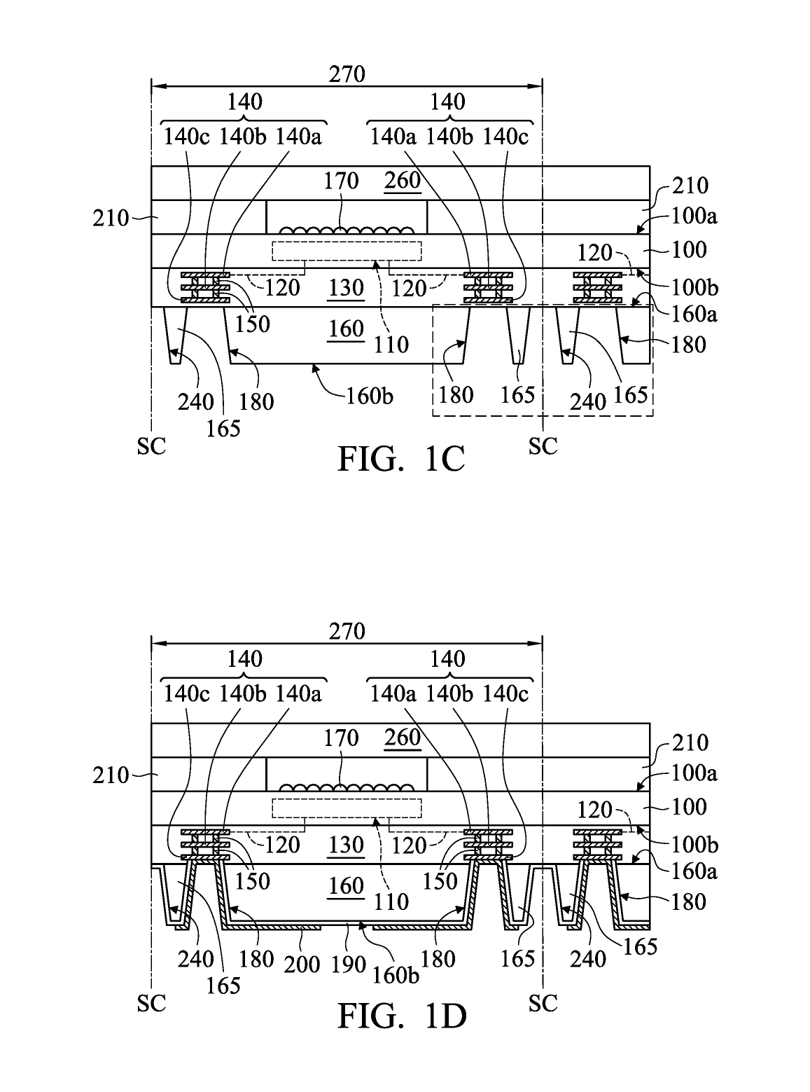

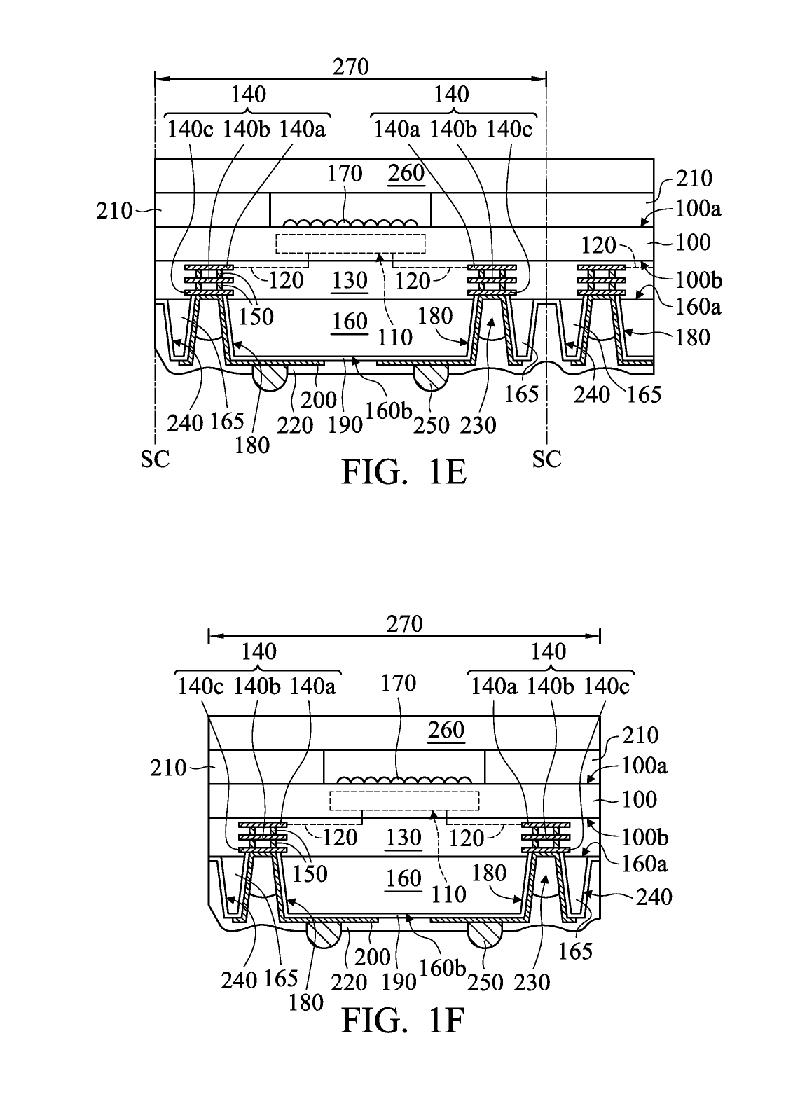

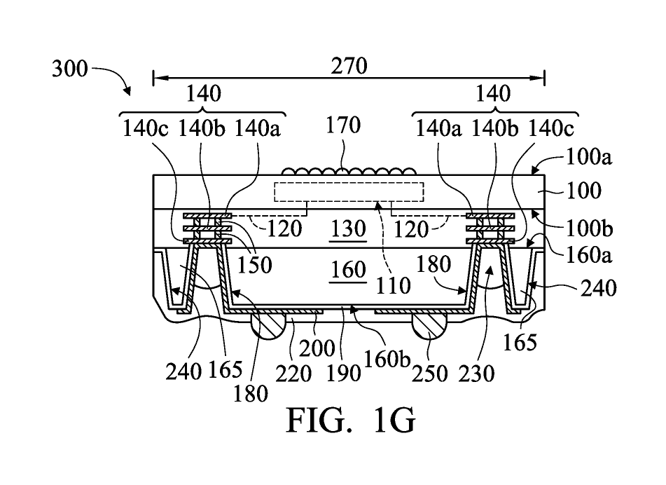

Referring to FIG. 1G, a cross-sectional view of an exemplary embodiment of a chip package 300 according to the invention is illustrated. In the description of the embodiment of the invention, a backside illumination (BSI) sensor device is depicted herein as an example. However, the embodiment of the invention is not limited to any specific application. In the embodiment, the chip package 300 includes a first substrate 100, a dielectric layer 130, a second substrate 160, and a redistribution layer (RDL) 200.

The first substrate 100 has a first surface 100a and a second surface 100b opposite thereto, and the first surface 100a is a flat surface. In the embodiment, the first substrate 100 may be a silicon substrate or another suitable semiconductor substrate, and the first substrate 100 includes a device region 110. The device region 110 may comprise an image sensor device (e.g., a photodiode, a phototransistor, or other light sensor devices) or other electronic devices of the integrated circuit. Moreover, the first substrate 100 may include integrated circuits (e.g., complementary metal oxide semiconductor (CMOS) transistors, resistors, or other semiconductor devices) for controlling such an image sensor device.

In one embodiment, an optical device 170 may be disposed on the first surface 100a of the first substrate 100 and correspond to the device region 110. For example, the optical device 170 may comprise a microlens array, a color filter array or a combination thereof or other suitable optical devices therein and be used for the image sensor device.

The dielectric layer 130 is disposed on the second surface 100b of the first substrate 100, the dielectric layer 130 includes one or more conducting pad structures 140 therein, and the first substrate 100 fully covers the conducting pad structure 140. Namely, there is not a through opening formed in the first substrate 100 and corresponding to the conducting pad structure 140. In the embodiment, the dielectric layer 130 may be formed of a single dielectric layer or multiple dielectric layers (e.g., silicon oxide, silicon nitride, silicon oxynitride or a combination thereof or other suitable dielectric materials). In one embodiment, the conducting pad structure 140 may include a single conducting pad or multiple conducting pads that are electrically connected to each other and have a vertical stacking arrangement, and be formed of a conducting material (e.g., copper, aluminum, or an alloy thereof or other suitable pad materials). In order to simplify the diagram, herein three conducting pads 140a, 140b, and 140c that have a vertical stacking arrangement are used for an exemplary description, and merely two conducting pad structures 140 in a single dielectric layer 130 are depicted for the exemplary description. The conducting pad 140a, the conducting pad 140b, and the conducting pad 140c in the dielectric layer 130 are spaced apart from each other and electrically connected to each other via the conducting plugs 150. Moreover, the conducting pad 140c, the conducting pad 140b, and the conducting pad 140a are successively arranged in a vertical stack along a direction from the second surface 100b toward the first surface 100a. The conducting pad structures 140 may be electrically connected to the device region 110 via an interconnect structure. In order to simplify the diagram, herein a dashed line is used to depict the interconnect structure 120 for electrical connection between the conducting pad 140a and the device region 110.

The second substrate 160 is disposed on the second surface 100b of the first substrate 100, and the dielectric layer 130 is interposed between the first substrate 100 and the second substrate 160. The second substrate 160 has a first surface 160a adjacent to the dielectric layer 130 and a second surface 160b opposite thereto. In one embodiment, the second substrate 160 may be a substrate without any device formed therein. Moreover, the second substrate 160 includes a first opening 180 exposing the surface of one of conducting pads in the conducting pad structure 140 (e.g., the surface of the conducting pad 140c). In the embodiment, the first opening 180 has a first side exposing the surface of the conducting pad structure 140 and a second side opposite thereto, in which the size of the first opening 180 at the first side is smaller than that of the first opening 180 at the second side. Moreover, the second substrate 160 further includes a second opening 240. The second opening 240 extends along the sidewall of the second substrate 160 and passes through the second substrate 160, so that a sidewall portion 165 formed of the second substrate 160 is formed between the first opening 180 and the second opening 240. In the embodiment, the sidewall portion 165 has a thickness that is equal to that of the second substrate 160, so that the first opening 180 is disconnected from the second opening 240.

An insulating layer 190 is conformally disposed on the second surface 160b of the second substrate 160, extends into the first opening 180, and exposes the surface of the conducting pad 140c. In the embodiment, the insulating layer 190 may comprise an epoxy, an inorganic material (e.g., silicon oxide, silicon nitride, silicon oxynitride, metal oxide, or a combination thereof), an organic polymer material (e.g., polyimide, butylcyclobutene (BCB), parylene, polynaphthalenes, fluorocarbons, or acrylates), or other suitable insulating materials.

The RDL 200 is disposed on the insulating layer 190, conformally extends into the first opening 180, located on the exposed surface of the conducting pad structure 140 (i.e., the RDL 200 extends on the surface of the conducting pad 140c), and does not extend into the second opening 240. In some embodiments, the RDL 200 may directly and electrically contact the exposed conducting pad 140c via the first opening 180 or be indirectly and electrically connected thereto. Accordingly, the RDL 200 in the first opening 180 is also referred to as a through substrate via (TSV), and the RDL 200 is electrically insulated from the second substrate 160 by the insulating layer 190. In one embodiment, the RDL 200 may comprise copper, aluminum, gold, platinum, nickel, tin, a combination thereof, a conducting polymer material, a conducting ceramic material (e.g., indium tin oxide or indium zinc oxide), or other suitable conducting materials.

A passivation layer 220 is disposed on the second surface 160b of the second substrate 160, and partially fills the first opening 180 and the second opening 240 to cover the RDL 200. In one embodiment, the passivation layer 220 may comprise an epoxy, a solder mask, an inorganic material (e.g., silicon oxide, silicon nitride, silicon oxynitride, metal oxide, or a combination thereof), an organic polymer material (e.g., polyimide, butylcyclobutene (BCB), parylene, polynaphthalenes, fluorocarbons, or acrylates), or other suitable insulating materials.

In one embodiment, the passivation layer 220 may have an uneven surface. Moreover, the passivation layer 220 does not fully fill the first opening 180, so that a cavity 230 is formed between the RDL 200 and the passivation layer 220 in the first opening 180. For example, the cavity 230 has an arch contour that protrudes toward the passivation layer 220.

The passivation layer 220 on the second surface 160b of the second substrate 160 has openings to expose a portion of the RDL 200. Moreover, conducting structures 250 (e.g., solder balls, bumps or conducting posts) are respectively disposed in the openings of the passivation layer 220, thereby being electrically connected to the exposed RDL 200. In one embodiment, the conducting structure 250 may comprise a solder ball and be formed of tin, lead, copper, gold, nickel, or a combination thereof

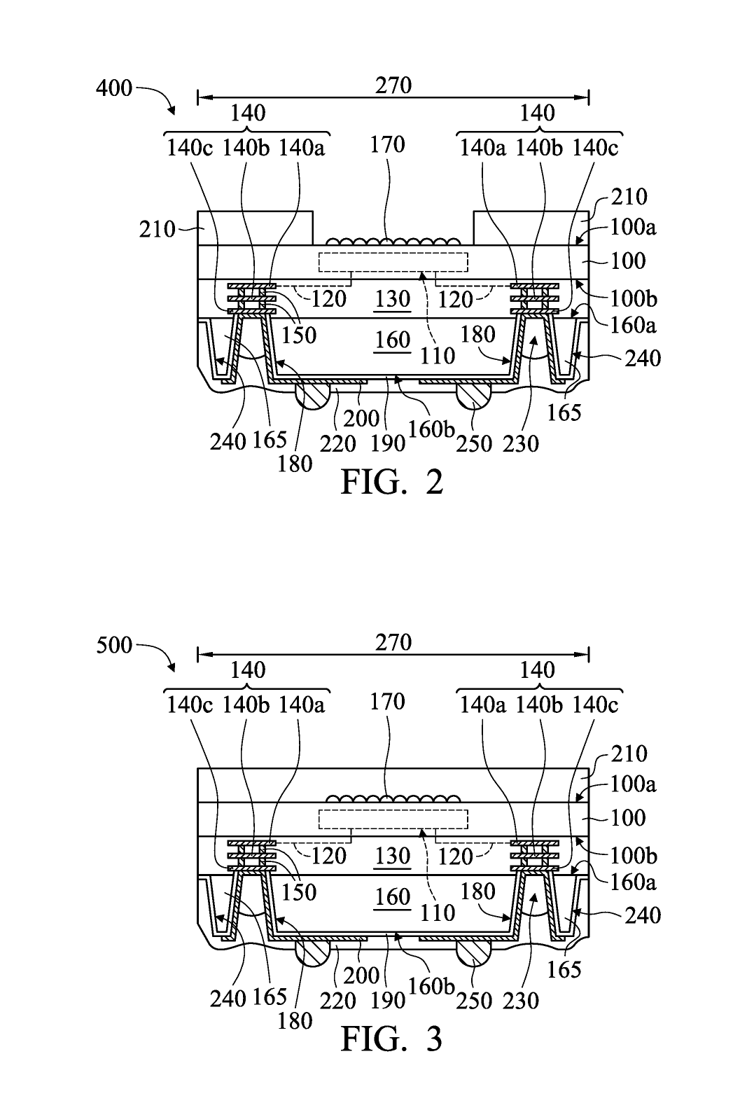

Refer to FIGS. 2, 3, and 4E, which respectively illustrate a cross-sectional view of an exemplary embodiment of chip packages 400, 500, and 600 according to the invention. Elements in these figures that are the same as or similar to those in FIG. 1G are not described again for brevity.

The structures of the chip packages 400 and 500 shown in FIGS. 2 and 3 are similar to the chip package 300 shown in FIG. 1G. The difference is the chip packages 400 and 500 further including a spacer layer (or referred to as a dam) 210 that is disposed on the first surface 100a of the first substrate 100. In the embodiment of FIG. 2, the spacer layer 210 surrounds the device region 110. In the embodiment of FIG. 3, the spacer layer 210 covers the optical device 170. In one embodiment, the spacer layer 210 is substantially unabsorbed moisture. In one embodiment, the spacer layer 210 may has a stickiness to serve as a temporary adhesion layer (e.g., a removable tape), the sticky spacer layer 210 may not be in contact with any adhesive glue, so as to ensure that the spacer layer 210 does not shift from its position due to the adhesive glue. Moreover, since there is no need to use the adhesive glue, the contamination of the optical device 170 due to the overflow of the adhesive glue can be eliminated. In the embodiment, the spacer layer 210 may comprise an epoxy, an inorganic material (e.g., silicon oxide, silicon nitride, silicon oxynitride, metal oxide, or a combination thereof), an organic polymer material (e.g., polyimide, BCB, parylene, polynaphthalenes, fluorocarbons, or acrylates), a photoresist material, or other suitable insulating materials.

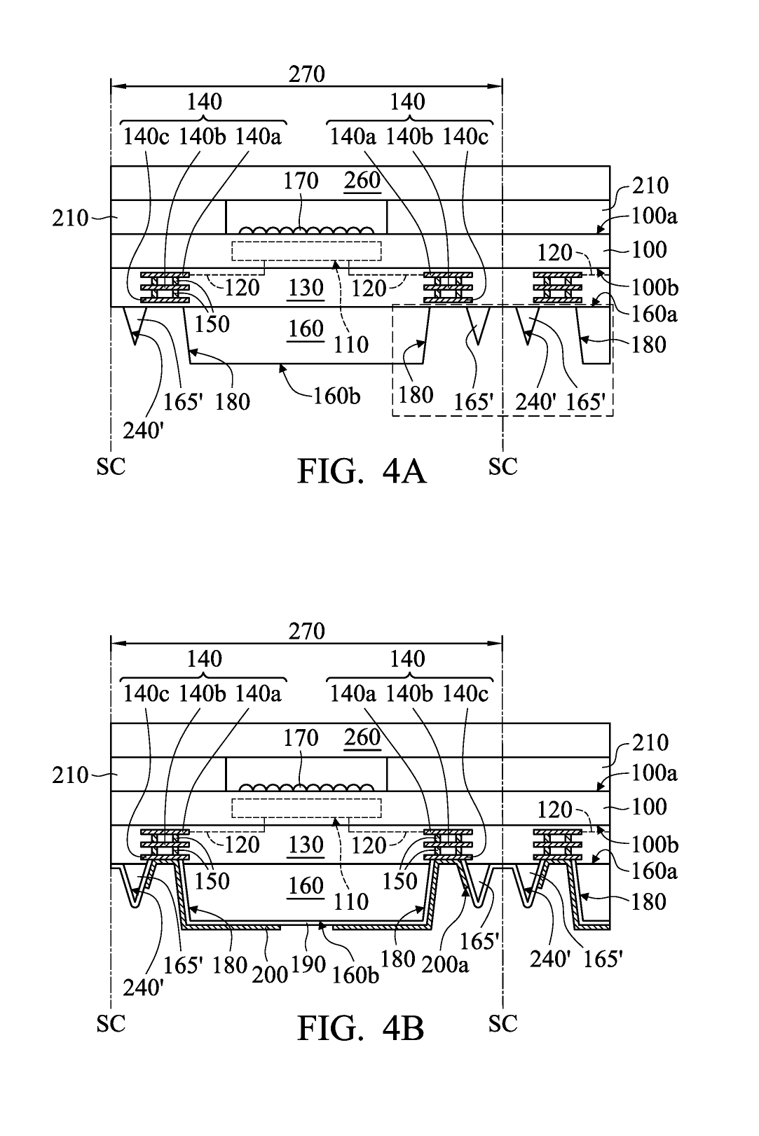

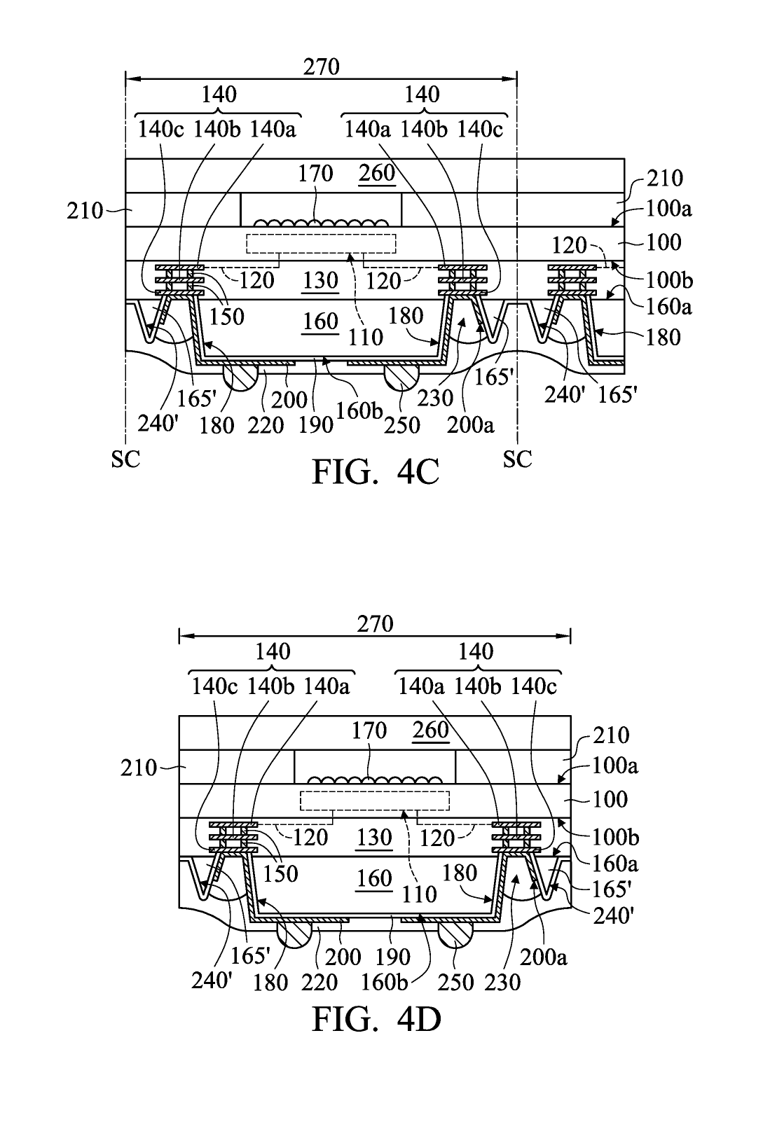

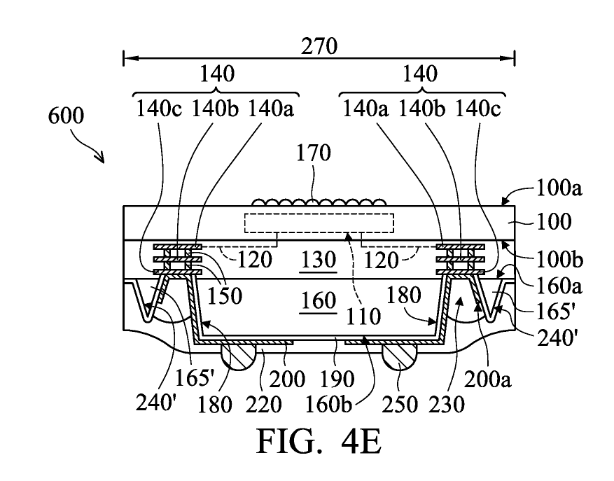

The structure of the chip package 600 shown in FIG. 4E is similar to that of the chip package 300 shown in FIG. 1G. The difference is the sidewall portion 165′ between the first opening 180 and the second opening 240 in the second substrate 160 of the chip package 600 has a smaller thickness than that of the second substrate 160, so that the first opening 180 is connected to the second opening 240.

According to the foregoing embodiments, since the first substrate 100 does not have an opening exposing the conducting pad structure 140, the first substrate 100 can fully cover the conducting pad structure 140, so as to increase the average thickness of the chip package. As a result, the structural strength and the reliability of the chip package can be increased.

Refer to FIGS. 1A to 1G, which illustrate cross-sectional views of an exemplary embodiment of a method for forming a chip package 300 according to the invention.

In FIG. 1A, a first substrate 100 having a first surface 100a and a second substrate 100b opposite thereto, and including a plurality of chip regions is provided. In order to simplify the diagram, herein only an entire chip region 270 and a portion of another chip region adjacent thereto are depicted. There is a scribe line SC between the chip regions 270. In one embodiment, the first substrate 100 may be a silicon substrate or other suitable semiconductor substrates. In another embodiment, the first substrate 100 is a silicon wafer for facilitating the wafer-level packaging process.

The first surface 100a of the first substrate 100 is a flat surface, and the first substrate 100 in the chip region 270 includes a device region 110. The device region 110 may comprise an image sensor device (e.g., a photodiode, a phototransistor, or other light sensor devices) or other electronic devices of the integrated circuit. Moreover, the first substrate 100 may include integrated circuits (e.g., CMOS transistors, resistors, or other semiconductor devices) for controlling such an image sensor device.

The second surface 100b of the first substrate 100 has a dielectric layer 130 thereon. The dielectric layer 130 includes one or more conducting pad structures 140 therein, and there is not a through opening exposing the conducting pad structure 140 and formed in the first substrate 100. In the embodiment, the dielectric layer 130 may be formed of a single dielectric layer or multiple dielectric layers (e.g., silicon oxide, silicon nitride, silicon oxynitride or a combination thereof or other suitable dielectric materials). In one embodiment, the conducting pad structure 140 may include a single conducting pad or multiple conducting pads that are electrically connected to each other and have a vertical stacking arrangement, and be formed of a conducting material (e.g., copper, aluminum, or an alloy thereof or other suitable pad materials). In order to simplify the diagram, herein three conducting pads 140a, 140b, and 140c that have a vertical stacking arrangement are used for an exemplary description, and merely two conducting pad structures 140 in a single dielectric layer 130 are depicted for the exemplary description. The conducting pad 140a, the conducting pad 140b, and the conducting pad 140c in the dielectric layer 130 are spaced apart from each other and electrically connected to each other via the conducting plugs 150. Moreover, the conducting pad 140c, the conducting pad 140b, and the conducting pad 140a are successively arranged in a vertical stack along a direction from the second surface 100b toward the first surface 100a. The conducting pad structures 140 may be electrically connected to the device region 110 via an interconnect structure. In order to simplify the diagram, herein a dashed line is used to depict the interconnect structure 120 for electrical connection between the conducting pad 140a and the device region 110.

Next, a second substrate 160 is formed on the second surface 100b of the first substrate 100, in which the dielectric layer 130 is interposed between the first substrate 100 and the second substrate 160. In the embodiment, the second substrate 160 may be a substrate without any device formed therein.

After the second substrate 160 is formed, an optical device 170 may be formed on the first surface 100a of the first substrate 100 and correspond to the device region 110. In the embodiment, the optical device 170 may comprise a microlens array, a color filter array or a combination thereof or other suitable optical devices therein and be used for the image sensor device.

Refer to FIG. 1B, a cover plate 260 is bonded on the first surface 100a of the first substrate 100 via the formation of a spacer layer (or is referred to as a dam) 210. The cover plate 260 is used for several functions, such as carrying, support, and protection. In the embodiment, the spacer layer 210 surrounds the device region 110, and the cover plate 260 covers the spacer layer 210 and the device region 110. In some embodiments, the spacer layer 210 may fully cover the optical device 170 and the first substrate 100, and the cover plate 260 may be formed on the spacer layer 210 and the optical device 170. In one embodiment, the spacer layer 210 is substantially unabsorbed moisture. In one embodiment, the spacer layer 210 may has a stickiness to serve as a temporary adhesion layer (e.g., a removable tape), the sticky spacer layer 210 may not be in contact with any adhesive glue to ensure that the spacer layer 210 does not shift from its position due to the adhesive glue. Moreover, since there is no need to use the adhesive glue, the contamination of the optical device 170 due to the overflow of the adhesive glue can be eliminated. In the embodiment, the spacer layer 210 may comprise an epoxy, an inorganic material (e.g., silicon oxide, silicon nitride, silicon oxynitride, metal oxide, or a combination thereof), an organic polymer material (e.g., polyimide, BCB, parylene, polynaphthalenes, fluorocarbons, or acrylates), a photoresist material, or other suitable insulating materials. In one embodiment, the cover plate 260 may comprise glass or other suitable substrate materials.

Refer to FIG. 1C, after the optical device 170, the spacer layer 210, and the cover plate are successively formed on the first surface 100a of the first substrate 100a, a thinning process (e.g., an etching, milling, or polishing process) is performed on the second surface 160b of the second substrate 160 by using the cover plate 260 as a carrier substrate, so as to reduce the thickness of the second substrate 160 (e.g., less than about 100 μm).

Next, a plurality of first openings 108 and a second opening 240 are simultaneously formed in the second substrate 160 of each chip region 270 by the lithography process and the etching process (e.g., a dry etching process, a wet etching process, a plasma etching process, a reactive ion etching process, or other suitable etching processes). The first openings 180 and the second openings 240 expose the dielectric layer 130. In some embodiments, the first openings 180 and the second opening 240 can be formed by the notching process and the lithography and etching processes. In the embodiment, the first openings 180 correspond to the conducting pad structures 140 and pass through the second substrate 160.

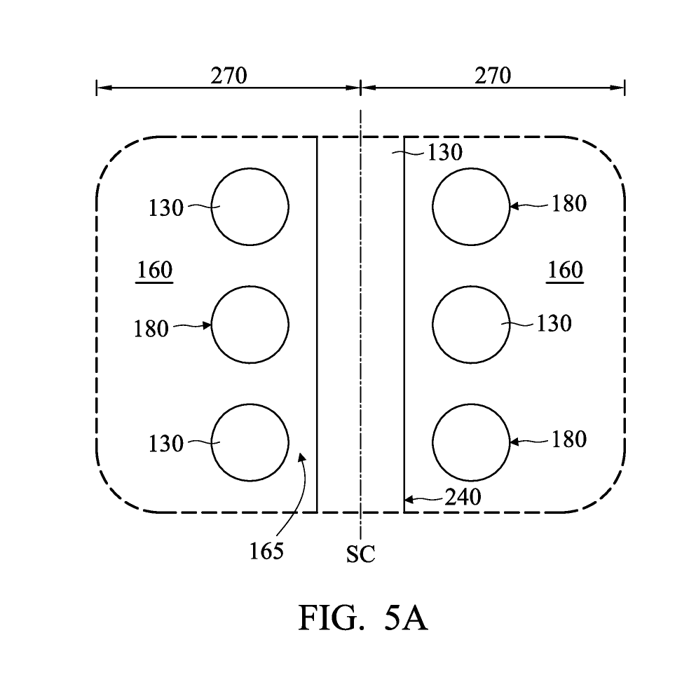

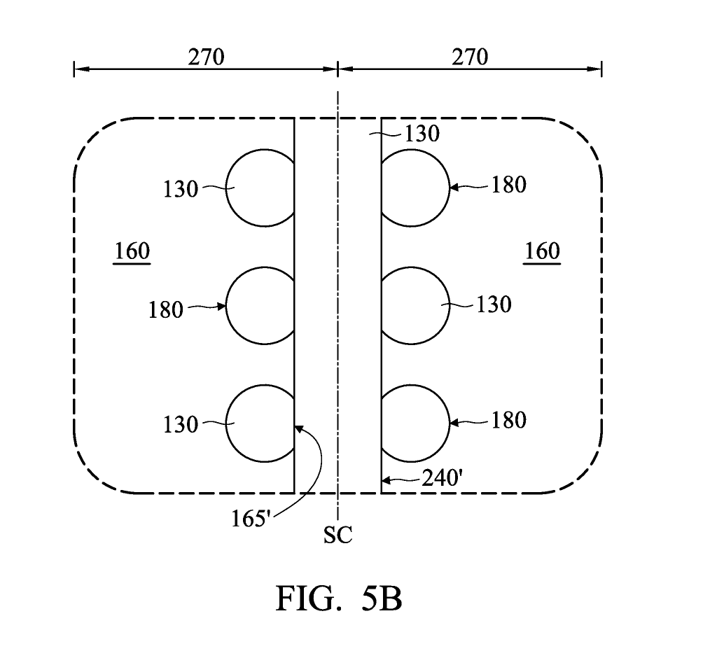

The second opening 240 extends along the scribe line SC between the adjacent chip regions 270 and pass through the second substrate 160, so that the second substrates 270 of the adjacent chip regions 160 are separated from each other. As shown in FIG. 5A, the first openings 180 in the two adjacent chip regions 270 are spaced and arranged along the extending direction of the second opening 240, and there is a sidewall portion 165 between the first opening 180 and the second opening 240. The sidewall portion 165 has a thickness that is equal to that of the second substrate 160, so that the first opening 180 is disconnected from the second opening 240.

In one embodiment, the second opening 240 may extend along the chip region 270 to surround the first openings 180. In the embodiment, the top-view contour of the first opening 180 is different from that of the second opening 240. For example, the first opening 180 has a circular-shaped top-view contour and the second opening 240 has a rectangular-shaped or rectangular ring-shaped top-view contour, as shown in FIG. 5A. It is understood that the first opening 180 and the second opening 240 may have other top-view contours and are not limited thereto.

Refer to FIG. 1D, an insulating layer 190 is conformally formed on the second surface 160b of the second substrate 160 and conformally formed on the sidewalls and the bottoms of the first openings 180 and the second opening 240 by a coating process or a deposition process (e.g., a physical vapor deposition process, a chemical vapor deposition process, or other suitable deposition processes). In the embodiment, the insulating layer 190 may comprise an epoxy, an inorganic material (e.g., silicon oxide, silicon nitride, silicon oxynitride, metal oxide, or a combination thereof), an organic polymer material (e.g., polyimide, BCB, parylene, polynaphthalenes, fluorocarbons, or acrylates), or other suitable insulating materials.

Next, the insulating layer 190 and a portion of the underlying dielectric layer 130 at the bottoms of the first openings 180 may be removed by the lithography and etching processes, so that the first opening 180 extends into the dielectric layer 130 to expose the surface of one of the conducting pads in the corresponding conducting pad structure 140 (e.g., the surface of the conducting pad 140c). In the embodiment, the first opening 180 has a first side exposing the surface of the conducting pad structure 140 and a second side opposite thereto, in which the size of the first opening 180 at the first side is smaller than that of the first opening 180 at the second side. Accordingly, the layers (e.g., the insulating layer and the RDL) to be subsequently formed in the first opening 180 can be easily deposited on the corners of the bottom (near the first side) of the first opening 180, thereby preventing from impacting the electrical connecting path or inducing leakage.

A patterned RDL 200 is formed on the insulating layer 190 by a coating or deposition process (e.g., a physical vapor deposition process, a chemical vapor deposition process, a plating process, an electroless plating process, or other suitable deposition processes), a lithography process, and an etching process. The RDL 200 is conformally formed on the sidewall and the bottom of the first opening 180, and does not extend into the second opening 240. The RDL 200 extends on the sidewall portion 165 between the first opening 180 and the second opening 240. The RDL 200 can be electrically isolated from the second substrate 160 by the insulating layer 190 and can directly and electrically contact the exposed conducting pad 140c via first opening 180 or be indirectly and electrically connected thereto. In one embodiment, the RDL 200 may comprise aluminum, copper, gold, platinum, nickel, tin, a combination thereof, a conducting polymer material, a conducting ceramic material (e.g., indium tin oxide or indium zinc oxide), or other suitable conducting materials.

Refer to FIG. 1E, a passivation layer 220 is formed on the second surface 160b of the second substrate 160, partially fills the first opening 180 and the second opening 240, and is on the RDL 200. In one embodiment, the passivation layer 220 may comprise an epoxy, a solder mask, an inorganic material (e.g., silicon oxide, silicon nitride, silicon oxynitride, metal oxide, or a combination thereof), an organic polymer material (e.g., polyimide, BCB, parylene, polynaphthalenes, fluorocarbons, or acrylates), or other suitable insulating materials.

In the embodiment, the passivation layer 220 does not fully fill the first opening 180, so that a cavity 230 is formed between the RDL 200 and the passivation layer 220 in the first opening 180, in which the cavity 230 has an arch contour that protrudes toward the passivation layer 220. Since the passivation layer 220 partially fills the first opening 180 to form the cavity 230, the cavity 230 can serve as a buffer between the passivation layer 220 and the RDL 200 while performing the heat treatment in the subsequent process steps. As a result, the undesired stress due to the coefficient of thermal expansion (CTE) mismatch between the passivation layer 220 and the RDL 200 can be reduced. Moreover, the RDL 200 can be prevented from being excessively pulled by the passivation layer 220 due to rapid changes in external temperature and pressure, thereby preventing the open circuit due to the delamination of the RDL 200 near the conducting pad structure 400.

Next, openings are formed in the passivation layer 220 on the second surface 160b of the second substrate 160 by the lithography and etching processes, to expose a portion of patterned RDL 200. Next, conducting structures 250 (e.g., solder balls, bumps, or conducting posts) are filled into the openings in the passivation layer 220, so as to be electrically connected to the exposed RDL 200. In one embodiment, the conducting structure 250 may comprise tin, lead, copper, gold, nickel, or a combination thereof

Next, the second substrate 160 and the first substrate 100 are successively diced along the second opening (i.e., along the scribe line) to form individual chip packages, as shown in FIG. 1F. For example, a laser dicing process may be performed to prevent the upper and lower films from being displaced.

Refer to FIG. 1G, after the formation of the individual chip packages, the cover plate 260 and the spacer layer 210 are removed from the first surface 100a of the first substrate 100, so as to expose the optical device 170. In some embodiments, the spacer layer 210 remains on the first surface 100b of the first substrate 100.

Refer to FIGS. 4A to 4E, which illustrate cross-sectional views of another exemplary embodiment of a method for forming a chip package 600 according to the invention. Elements in these figures that are the same as or similar to those in FIGS. 1A to 1G are not described again for brevity. For the description of the embodiment of the invention, herein a BSI sensor device is depicted as an example. However, the embodiment of the invention is not limited to any specific application.

Refer to FIG. 4A, a structure shown in the embodiment of FIG. 1B is provided. A thinning process (e.g., an etching, milling, grinding, or polishing process) is performed on the second surface 160b of the second substrate 160 by using the cover plate 260 as a carrier substrate, so as to reduce the thickness of the second substrate 160.

Next, a plurality of first openings 108 and a second opening 240′ are simultaneously formed in the second substrate 160 of each chip region 270 by the lithography process and the etching process (e.g., a dry etching process, a wet etching process, a plasma etching process, a reactive ion etching process, or other suitable etching processes). The first openings 180 and the second opening 240′ expose the dielectric layer 130. In some embodiments, the first openings 180 and the second opening 240′ can be formed by a notching process and lithography and etching processes. In the embodiment, the first openings 180 correspond to the conducting pad structures 140 and pass through the second substrate 160.

The opening 240′ is similar to the opening 240 shown in FIG. 1C. As shown in FIG. 5B, which illustrates a bottom view of the region enclosed by a dashed line in the chip package shown in FIG. 4A. The first openings 180 in the two adjacent chip regions 270 are spaced and arranged along the extending direction of the second opening 240′, and there is a sidewall portion 165′ between the first opening 180 and the second opening 240′. Unlike the embodiment shown in FIGS. 1C and 5A, in the embodiment, the sidewall portion 165′ has a thickness that is less than that of the second substrate 160, so that the first openings 180 are connected to the second opening 240′.

The first opening 180 and the second opening 240′ are connected from each other, rather than being fully isolated from each other by a portion of the second substrate 160 (i.e., the sidewall portion 165′), so as to prevent the stress from accumulating at the sidewall portion 165′ of the second substrate 160 between the first opening 180 and the second opening 240′. Moreover, the stress can be mitigated and released by the second opening 240′, thereby preventing the sidewall portion 165′ of the second substrate 160 from cracking.

Refer to FIG. 4B, an insulating layer 190 is conformally formed on the second surface 160b of the second substrate 160 and conformally formed on the sidewalls and the bottoms of the first openings 180 and the second opening 240′ by a coating process or a deposition process (e.g., a physical vapor deposition process, a chemical vapor deposition process, or other suitable deposition processes). Next, the insulating layer 190 and a portion of the underlying dielectric layer 130 at the bottoms of the first openings 180 may be removed, so that the first opening 180 extends into the dielectric layer 130 to expose the surface of one of the conducting pads in the corresponding conducting pad structure 140. As mentioned in the foregoing embodiments, the first opening 180 has a first side exposing the surface of the conducting pad structure 140 and a second side opposite thereto, in which the size of the first opening 180 at the first side is smaller than that of the first opening 180 at the second side.

Thereafter, a patterned RDL 200 is formed on the insulating layer 190. The RDL 200 is conformally formed on the sidewall and the bottom of the first opening 180, and does not extend into the second opening 240′. The RDL 200 extends on the sidewall portion 165′ between the first opening 180 and the second opening 240′. Moreover, since the first opening 180 and the second opening 240 are connected to each other, one end 200a of the RDL 200 merely extends to the sidewall of the first opening 180 and does not cover the top surface of the sidewall portion 165′.

Refer to FIG. 4C, a passivation layer 220 is formed on the second surface 160b of the second substrate 160, partially fills the first openings 180 and the second opening 240, and is on the RDL 200.

As mentioned in the foregoing embodiments, the passivation layer 220 does not fully fill the first opening 180, so that a cavity 230 is formed between the RDL 200 and the passivation layer 220 in the first opening 180. The end 200a of the RDL 200 is in the cavity 230 in the first opening 180, and the cavity 230 has an arch contour that protrudes toward the passivation layer 220. The cavity 230 can serve as a buffer between the passivation layer 220 and the RDL 200, and prevent the delamination of the RDL 200 near the conducting pad structure 400.

Next, openings are formed in the passivation layer 220 on the second surface 160b of the second substrate 160 to expose a portion of patterned RDL 200. Next, conducting structures 250 (e.g., solder balls, bumps, or conducting posts) are filled into the openings in the passivation layer 220, so as to be electrically connected to the exposed RDL 200.

Thereafter, the second substrate 160 and the first substrate 100 are successively diced along the second opening 240′ (i.e., along the scribe line) to form individual chip packages, as shown in FIG. 4D.

Refer to FIG. 4E, after the formation of the individual chip packages 600, the cover plate 260 and the spacer layer 210 are removed from the first surface 100a of the first substrate 100, so as to expose the optical device 170. In some embodiments, the spacer layer 210 remains on the first surface 100b of the first substrate 100.

According to the foregoing embodiments, since the first substrate 100 does not have an opening exposing the conducting pad structure 140 therein, there is no need to remove a portion of the first substrate 100 by the lithography process and the etching process (e.g., a dry etching process, a wet etching process, a plasma etching process, a reactive ion etching process, or other suitable processes), to expose the conducting pad 140 (i.e., the process steps are reduced). As a result, the manufacturing cost of the chip package is reduced.

Moreover, since the first substrate 100 does not have an opening exposing the conducting pad structure 140 therein, the first substrate 100 may have a flat first surface 100a (i.e., the surface is not undulated), so that the optical device 170 can be stably formed on the flat surface by using a single coating process, thereby reducing the cost of the optical device and enhancing the optical performance of the optical device.

Additionally, since the first substrate 100 does not have an opening exposing the conducting pad structure 140 therein, the first substrate 100 may provide a greater average thickness to support the dielectric layer 130, thereby preventing the dielectric layer 130 from cracking while forming the first opening 180 and the second opening 240. As a result, the structural strength of the chip package is enhanced.

Moreover, it is helpful to greatly reduce the entire height of the chip package and increase the transmission of the chip package by removing the cover plate 260 from the first substrate 100. Furthermore, since the cover plate 260 merely serves as a temporary substrate that does not impact the sensing ability of the chip package, there is no need to use a high quality glass material as the cover plate 260. Alternatively, an opaque substrate material may also be used for the cover plate 260.

While the invention has been disclosed in terms of the preferred embodiments, it is not limited. The various embodiments may be modified and combined by those skilled in the art without departing from the concept and scope of the invention.

What is claimed is:

1. A chip package, comprising:
a first substrate comprising a device region and having a first surface and a second surface opposite thereto;
a dielectric layer disposed on the second surface of the first substrate, wherein the dielectric layer comprises a conducting pad structure electrically connected to the device region, and wherein the first substrate completely covers the conducting pad structure;
a second substrate disposed on the second surface of the first substrate, wherein the dielectric layer is located between the first substrate and the second substrate, and wherein the second substrate has a first opening exposing a surface of the conducting pad structure; and
a redistribution layer conformally disposed on a sidewall of the first opening and the surface of the exposed conducting pad structure.

2. The chip package as claimed in claim 1, further comprising a spacer layer disposed on the first surface of the first substrate and surrounding the device region.

3. The chip package as claimed in claim 1, wherein the first surface of the first substrate is a flat surface.

4. The chip package as claimed in claim 1, further comprising an optical device disposed on the first surface of the first substrate and corresponding to the device region.

5. The chip package as claimed in claim 4, further comprising a spacer layer covering the optical device.

6. The chip package as claimed in claim 1, wherein the conducting pad arrangement, and the first opening exposes a surface of one of the plurality of conducting pads.

7. The chip package as claimed in claim 1, further comprising a passivation layer partially filling the first opening and disposed on the redistribution layer, so that a cavity is formed between the redistribution layer and the passivation layer in the first opening.

8. The chip package as claimed in claim 7, wherein the cavity has an arch contour that protrudes toward the passivation layer.

9. The chip package as claimed in claim 1, wherein the first opening has a first side exposing the surface of the conducting pad structure and a second side opposite thereto, and the size of the first opening at the first side is smaller than that of the first opening at the second side.

10. The chip package as claimed in claim 1, wherein second substrate further comprises a second opening extending along a sidewall of the second substrate and passing through the second substrate, so that a sidewall portion formed of the second substrate is formed between the first opening and the second opening.

11. The chip package as claimed in claim 10, wherein the sidewall portion has a smaller thickness than that of the second substrate, so that the first opening is connected to the second opening.

12. The chip package as claimed in claim 11, further comprising a passivation layer partially filling the first and second openings, so that a cavity is formed between the redistribution layer and the passivation layer in the first opening.

13. The chip package as claimed in claim 12, wherein the cavity has an arch contour that protrudes toward the passivation layer.

14. The chip package as claimed in claim 10, wherein the sidewall portion has a thickness that is equal to that of the second substrate, so that the first opening is disconnected from the second opening.

15. A method for forming a chip package, comprising:
providing a first substrate comprising a device region and having a first surface and a second surface opposite thereto, wherein the second surface of the first substrate has a dielectric layer thereon and the dielectric layer comprises a conducting pad structure electrically connected to the device region, and wherein the first substrate does not have an opening exposing the conducting pad structure;
forming a second substrate on the second surface of the first substrate, wherein the dielectric layer is located between the first substrate and the second substrate;
forming a first opening passing through the second substrate and extending into the dielectric layer to expose a surface of the conducting pad structure;
conformally forming a redistribution layer on a sidewall of the first opening and the surface of the exposed conducting pad structure; and
successively dicing the second substrate and the first substrate.

16. The method for forming a chip package as claimed in claim 15, further successively forming a spacer layer and cover plate on the first surface of the first substrate prior to formation of the first opening, wherein the spacer layer surrounds the device region and the cover plate covers the spacer layer and the device region.

17. The method for forming a chip package as claimed in claim 15, wherein the first surface of the first substrate is a flat surface.

18. The method for forming a chip package as claimed in claim 15, further forming an optical device on the first surface of the first substrate and corresponding to the device region prior to formation of the first opening.

19. The method for forming a chip package as claimed in claim 18, further successively forming a spacer layer and cover plate on the first surface of the first substrate prior to formation of the first opening, wherein the spacer layer covers the optical device, and the cover plate covers the spacer layer and the optical device.

20. The method for forming a chip package as claimed in claim 15, wherein the conducting pad structure comprises a plurality of conducting pads with a vertical stacking arrangement, and the first opening exposes a surface of one of the plurality of conducting pads.

21. The method for forming a chip package as claimed in claim 15, further forming a passivation layer that partially fills the first opening and is on the redistribution layer, so that a cavity is formed between the redistribution layer and the passivation layer in the first opening.

22. The method for forming a chip package as claimed in claim 21, wherein the cavity has an arch contour that protrudes toward the passivation layer.

23. The method for forming a chip package as claimed in claim 15, wherein the first opening has a first side exposing the surface of the conducting pad structure and a second side opposite thereto, and the size of the first opening at the first side is smaller than that of the first opening at the second side.

24. The method for forming a chip package as claimed in claim 13, further forming a second opening in the second substrate before dicing the first and second substrates, wherein the second opening passes through the second substrate, so that a and the second opening, and wherein the second substrate is diced along the second opening.

25. The method for forming a chip package as claimed in claim 24, wherein the sidewall portion has a smaller thickness than that of the second substrate, so that the first opening is connected to the second opening.

26. The method for forming a chip package as claimed in claim 24, further forming a passivation layer that partially fills the first and second openings, so that a cavity is formed between the redistribution layer and the passivation layer in the first opening.

27. The method for forming a chip package as claimed in claim 26, wherein the cavity has an arch contour that protrudes toward the passivation layer.

28. The method for forming a chip package as claimed in claim 24, wherein the sidewall portion has a thickness that is equal to that of the second substrate, so that the first opening is disconnected from the second opening.
